(19) United States
(12) Patent Application Publication
(10) Pub. No.: US 2023/0042608 A1
(43) Pub. Date: Feb. 9, 2023

(54) Method for Measuring Dimensions Relative to Bounded Object

(71) Applicant: Multiscale Technologies, Inc., Atlanta, GA (US)

(72) Inventors: Srinivasa R Kalidindi, Kirkland, WA (US); Hyung Nun Kim, Boise, ID (US); Almambet Iskakov, Atlanta, GA (US)

(73) Assignee: Multiscale Technologies, Inc., Atlanta, GA (US)

(21) Appl. No.: 17/880,572

(22) Filed: Aug. 3, 2022

Related U.S. Application Data
(60) Provisional application No. 63/228,989, filed on Aug. 3, 2021.

(51) Int. Cl. G06T 7/62; G01N 23/04; G06T 7/136; G06T 7/11; G06T 5/00; G06T 7/00; H01J 37/22

(52) U.S. Cl. CPC G06T 7/62; G01N 23/04; G06T 7/136; G06T 7/11; G06T 5/002; G06T 7/0004; H01J 37/222; G01N 2223/401; G01N 2223/42; G06T 2207/10061; G06T 2207/30148; G06T 2207/20036; G06T 2207/20021; H01J 37/26

(57) ABSTRACT

A method for analyzing at least one bounded object in an electron microscope image that includes segmenting the image to provide a segmented image and measuring a dimension relative to the at least one bounded object in the segmented image. The electron microscope image can be an image of a semiconductor device that includes a pattern of bounded objects or structure of the semiconductor device.

### CROSS REFERENCE TO RELATED APPLICATION

This application claims priority to U.S. provisional patent application Ser. No. 63/228,989 filed Aug. 3, 2021, the entire content of which is incorporated herein by this reference.

### FIELD OF INVENTION

This invention relates to measuring dimensions of objects in CD-SEM or CD-TEM images, and more particularly to quantifying the measurements of the dimensions.

### BACKGROUND OF THE INVENTION

Critical-dimension scanning electron microscope (CD-SEM) images and critical-dimension transmission electron microscope (CD-TEM) images can be used to determine dimensions on images of semiconductor wafers. In many cases, an interest is to quantify the measurements of the dimensions, which is important in validating design specifications of the semiconductor wafer. However, current state of the art methodologies for quantification typically directly utilize raw grayscale contrast levels of an image, which often exhibit significant noise, to obtain dimensions of features in the CD-SEM or CD-TEM image.

### BRIEF DESCRIPTION OF THE DRAWINGS

The drawings herein are schematic and not drawn to scale and are for illustration purposes only and are not intended to limit the scope of the present disclosure.

FIG. 1 is a flow diagram of an embodiment of the method for measuring fine dimensions of the present invention for use with an image.

FIG. 2A is an example of an image for use in the method for measuring fine dimensions of the present invention.

FIG. 2B is a histogram corresponding to the image of FIG. 2A.

FIG. 2C is an image resulting from a contrast enhancement technique in the method for measuring fine dimensions of the present invention.

FIG. 2D is a histogram corresponding to the image of FIG. 2C.

FIG. 2E is an image resulting from a gradient noise reduction technique in the method for measuring fine dimensions of the present invention.

FIG. 2F is a histogram corresponding to the image of FIG. 2E.

FIG. 2G is an image resulting from a pixel-level noise reduction technique in the method for measuring fine dimensions of the present invention.

FIG. 2H is a histogram corresponding to the image of FIG. 2G.

FIG. 2I is an image resulting from a segmentation technique in the method for measuring fine dimensions of the present invention.

FIG. 2J is a histogram corresponding to the image of FIG. 2I.

FIG. 3A is an image resulting from a linear rescaling technique in the method for measuring fine dimensions of the present invention.

FIG. 3B is a histogram corresponding to the image of FIG. 3A.

FIG. 3C is an image resulting from a histogram equalization technique in the method for measuring fine dimensions of the present invention.

FIG. 3D is a histogram corresponding to the image of FIG. 3C.

FIG. 3E is an image resulting from an adaptive histogram equalization technique in the method for measuring fine dimensions of the present invention.

FIG. 3F is a histogram corresponding to the image of FIG. 3C.

FIG. 4A is a close-up view of a portion of the image in FIG. 3A.

FIG. 4B is a histogram corresponding to the image of FIG. 4A.

FIG. 4C is an image resulting from a Gaussian filtering technique applied to the image of FIG. 4A in the method for measuring fine dimensions of the present invention.

FIG. 4D is a histogram corresponding to the image of FIG. 4C.

FIG. 4E is an image resulting from a median filtering technique applied to the image of FIG. 4A in the method for measuring fine dimensions of the present invention.

FIG. 4F is a histogram corresponding to the image of FIG. 4E.

FIG. 4G is an image resulting from a bilateral filtering technique applied to the image of FIG. 4A in the method for measuring fine dimensions of the present invention.

FIG. 4H is a histogram corresponding to the image of FIG. 4G.

FIG. 4I is an image resulting from a non-local means filtering technique applied to the image of FIG. 4A in the method for measuring fine dimensions of the present invention.

FIG. 4J is a histogram corresponding to the image of FIG. 4I.

FIG. 5A is a sample pre-processed image of the invention, for example similar to FIG. 3A.

FIG. 5B is an enlarged portion of the image of FIG. 5A.

FIG. 5C is an image resulting from a global thresholding technique applied to the image of FIG. 5A in the method for measuring fine dimensions of the present invention.

FIG. 5D is an image resulting from a global segmentation technique applied to the image of FIG. 5B in the method for measuring fine dimensions of the present invention.

FIG. 5E is an image resulting from a local thresholding technique applied to the image of FIG. 5A in the method for measuring fine dimensions of the present invention.

FIG. 5F is an image resulting from a local thresholding technique applied to the image of FIG. 5B in the method for measuring fine dimensions of the present invention.

FIG. 6A is an image resulting from an image pre-processing step in the method for measuring fine dimensions of the present invention.

FIG. 6B is an image resulting from an image segmentation step applied to the image of FIG. 6A in the method for measuring fine dimensions of the present invention.

FIG. 6C is an image resulting from a segmentation correction technique applied to the image of FIG. 6B in the method for measuring fine dimensions of the present invention.

FIG. 6D is an image resulting from a binary erosion and dilation technique applied to the image of FIG. 6C in the method for measuring fine dimensions of the present invention.

FIG. 6E is an image resulting from morphological operation to remove objects touching the borders of an image applied to the image of FIG. 6D in the method for measuring fine dimensions of the present invention

FIG. 7 is an image resulting from a method of the invention with sample measurements shown thereon.

FIG. 8A is an image resulting from an image pre-processing step in the method for measuring fine dimensions of the present invention that includes anomalous objects.

FIG. 8B an image resulting from a segmentation correction technique applied to the image of FIG. 8A in the method for measuring fine dimensions of the present invention with sample measurements shown thereon.

### DETAILED DESCRIPTION OF THE INVENTION

A method for measuring and quantifying the fine dimensions from raw electron microscope images, including for example critical dimension scanning electron microscope (CD-SEM) images and critical dimension transmission electron microscope (CD-TEM) images, is provided. The method can optionally use pre-processing techniques, enhancement techniques, segmentation image analysis techniques, post-processing techniques or any combination of the foregoing. In some embodiments, the method includes at least any suitable segmentation image analysis technique. The image analysis workflow can be comprised of one or more of the following steps: image pre-processing, image segmentation, and image post-processing. The method is suited to semiconductor images, that is images of semiconductor devices.

Image pre-processing can optionally involve preliminary cleanup of the raw image, for example to facilitate an image segmentation step. The cleanup can pertain to features of interest in the image, including patterns of features of interest. The features of interest can be of any suitable type, including objects, bounded objects, closed objects, objects with closed borders, circular objects, elliptical objects, rectangular objects, cross sections of cylindrical features, other objects in patterns found in cross-sectional layers observed in the images, structures, objects found in semiconductor devices or any combination of the foregoing. For purposes herein, a bounded object can mean an object of one material surrounded by another material. Such patterns of features of interest can optionally be called fine patterns. The image pre-processing step can be performed in any suitable manner, including any known manner or technique. The image pre-processing step typically involves enhancing the quality of the image, and can optionally include methods or functions that modify the grayscale (or RGB) intensity values of the image, for example the grayscale intensity values or red, green and blue (RGB) intensity values of the image. The image pre-processing step can optionally include techniques such as filter-based or other image noise reduction techniques, contrast enhancement methods or both.

Image segmentation can optionally involve the process of assigning discrete values to each pixel or groups of pixels of the image, for example to enhance differentiation of the features of interest in the image from the remainder of the image so as to facilitate subsequent analysis of the features of interest or image. The image segmentation step can be performed in any suitable manner, including with any known manner or technique. Different algorithms exist to perform image segmentation, including for example global thresholding and local thresholding, by employing a grayscale intensity threshold to correctly assign the pixel state. The image segmentation step can optionally identify each pixel as a physically meaningful local state, for example identifying a pixel as a primary feature or as a background feature or identifying each pixel as a material phase 1 or a material phase 2. Global thresholding typically operates on the entire image whereas local thresholding typically applies a varying threshold that is determined within local neighborhoods. Global thresholding can optionally include OTSU global thresholding. Local thresholding can optionally include adaptive thresholding. Multi-thresholding techniques can optionally be utilized.

Image post-processing optionally involves image processing techniques used as a final or post segmentation cleanup. The image post-processing step can be performed in any suitable manner, including any known manner or technique, and for example can include segmentation correction and morphological operations. Segmentation correction can optionally include unit operators such as removing holes in segmented objects, removing segmented pixel level noise, removing segmented objects based on object morphology, removing segmented objects that are in contact with the image borders, removing segmented objects based on location of the object or any combination of the foregoing. Segmented pixel level noise can include any pixel level noise that was not removed in any pre-processing step. Morphological operations can optionally involve techniques that perform corrections on the segmented objects themselves, including for example eroding the objects to grow them or dilating the objects to shrink them.

The method of the invention can result in a segmented image comprised of two or more local states, for example if multiple thresholds were used for an image consisting of 3+ local states. These local states can optionally be labels given to each pixel in the segmented image that defines a feature class. Such a feature class can include, for example, bounded objects, closed objects, objects with closed borders, circular objects, elliptical objects, rectangular objects, cross sections of cylindrical features, other objects in patterns found in cross-sectional layers observed in the images, objects found in semiconductor devices or any combination of the foregoing. Fine dimensions can optionally be digitally measured from the segmented objects, which are the primary products of the image segmentation step. The segmented images, as optionally cleaned by the image post-processing step, can be used to measure pattern or other dimensions and identify anomalies in the structures shown in the images.

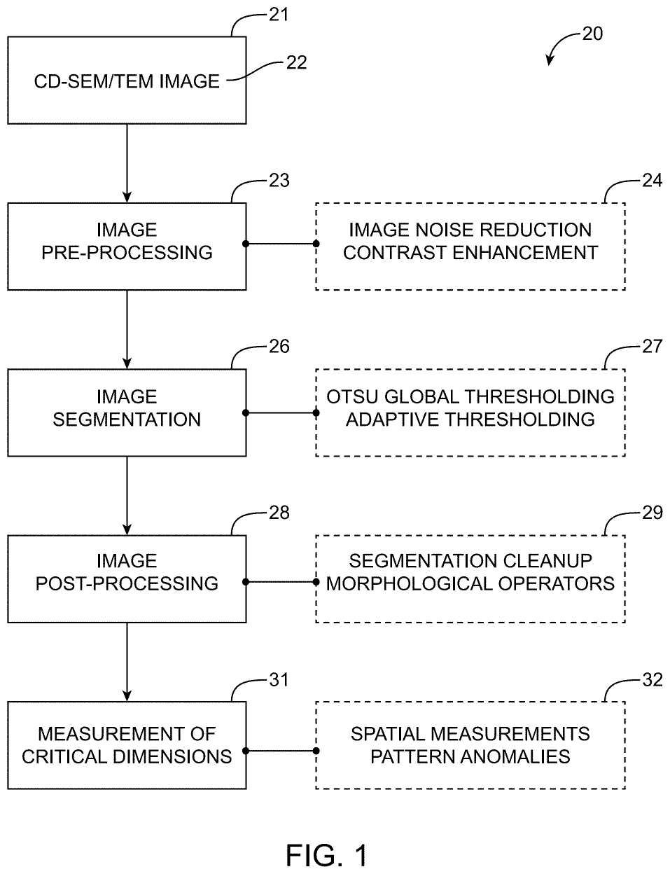

The method of the present invention can optionally be an image analysis workflow or recipe that utilizes techniques to measure and quantify the fine dimensions, including for example fine pattern dimensions, in electron microscope images, for example CD-SEM and CD-TEM images or other similar images. A sample workflow 20 is provided in FIG. 1. In step 21 of the workflow 20, an image 22, for example a CD-SEM image, a CD-TEM image or other electron microscope image, is provided. Step 21 can optionally include acquiring the image, for example by use of a suitable electron microscope. In step 23, which can optionally be called an image pre-processing step, the image 22 can be pre-processed in any suitable manner, for example as discussed above or otherwise herein. Step 23 can optionally include one or more image noise reduction techniques, one or more contrast enhancement techniques or one or more noise reduction and contrast enhancement techniques, as shown in step 24. Such techniques of step 24 can be of any suitable type, for example as discussed above or otherwise herein. In step 26, which can optionally be called an image segmentation step, the image 22, for example the pre-processed image of step 23, can be segmented in any suitable manner, for example as discussed above or otherwise herein. Step 26 can optionally include one or more OTSU or other global thresholding techniques, one or more local or adaptive or local thresholding techniques, one or more multi-thresholding techniques or any combination of the foregoing, for example as shown in step 27. Such thresholding techniques of step 27 can be of any suitable type, for example as discussed above or otherwise herein. In step 28, which can optionally be called an image post-processing step, the image 22, for example the segmented image from step 26, can be cleaned up or further processed in any suitable manner, for example as discussed above or otherwise herein. Step 28 can optionally include one or more segmentation cleanup or correction techniques, one or more morphological operators or operations or any combination of the foregoing, for example as shown in step 29. Such segmentation cleanup or correction techniques of step 29 and such morphological operators or operations of step 29 can each be of any suitable type, for example as discussed above or otherwise herein. In step 31, which can optionally be called an analysis or measurement step, the image 22, for example the segmented image from step 26, the post-processed image from step 28 or both, can be analyzed in any suitable or desired manner, for example as discussed above or otherwise herein. Step 31 can optionally include labeling features or objects in the image or making spatial measurements in the image, for example of features or objects in the image, as shown in step 32. Step 31 can optionally include observing anomalies in the images, for example of objects or patterns in the image, for example as shown in step 32.

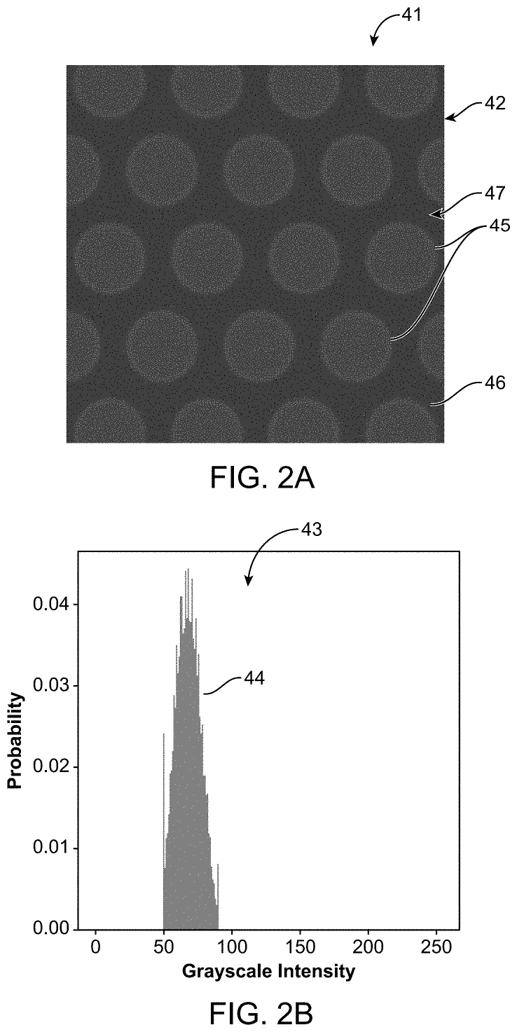

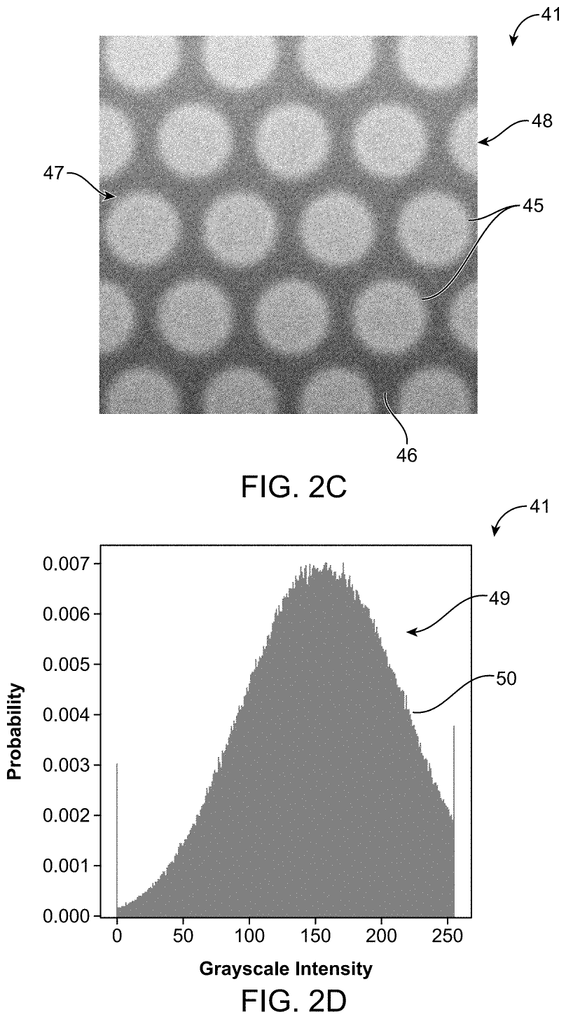

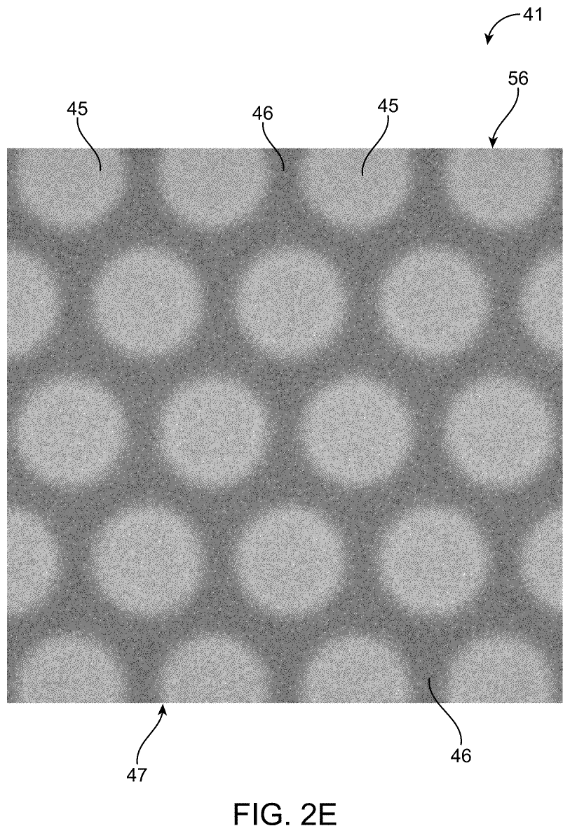

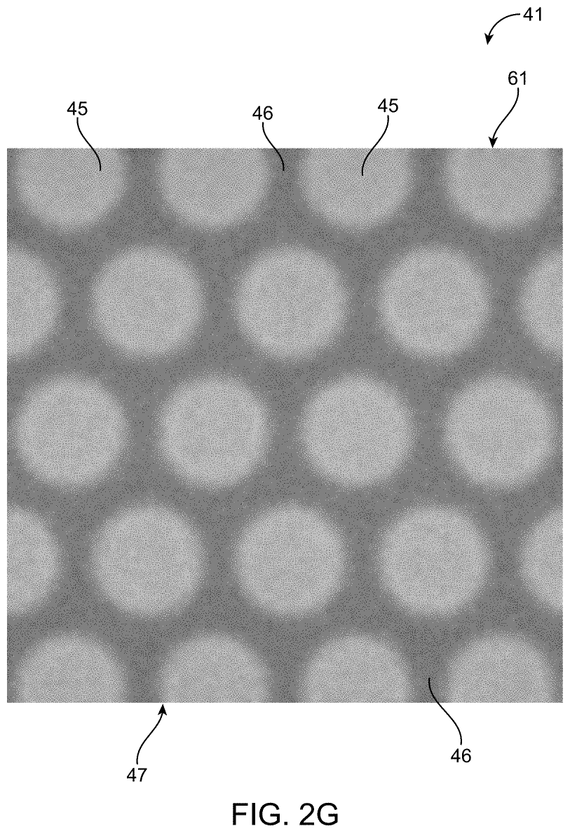

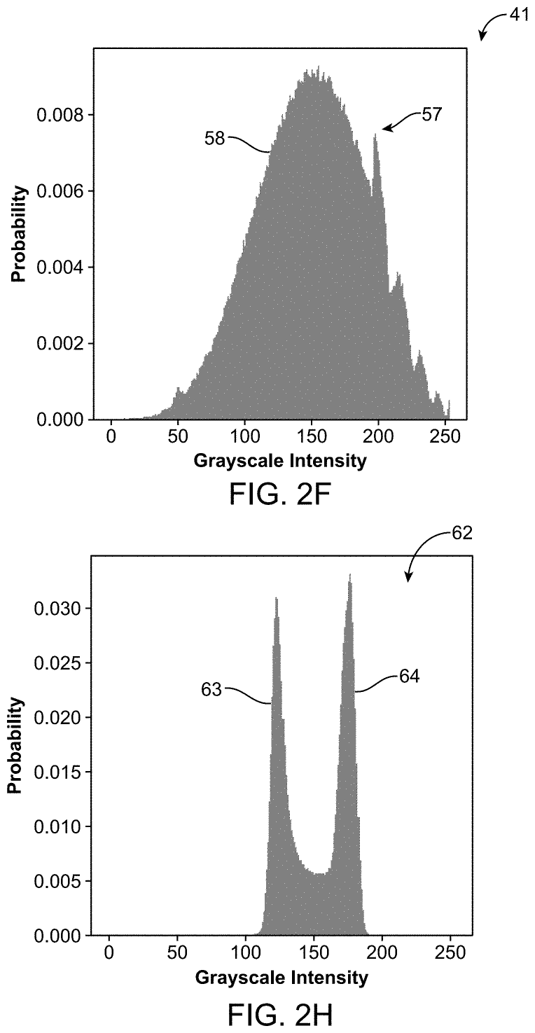

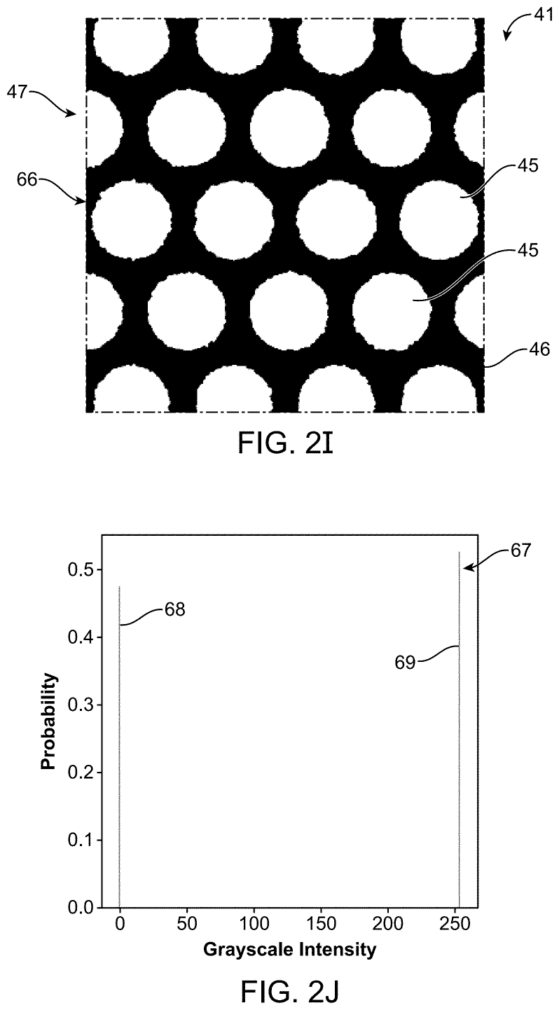

FIGS. 2A-2J illustrate an example image analysis workflow 41 for a CD-SEM, CD-TEM or other electron microscope image, for example image 22. The workflow shown in FIG. 2 can optionally include some or all of the steps of workflow 20. An acquired or otherwise provided image 42 is shown in FIG. 2A and the corresponding grayscale intensity histogram 43, which has a distribution approximating a parabolic curve 44, of image 42 is shown in FIG. 2B. The image 42 can optionally be a semiconductor image, that is an image from an integrated circuit or other semiconductor device. The image can optionally include one or more features of interest, for example a semiconductor feature or structure of interest. The semiconductor device can optionally include a plurality of three dimensional electrical components or structures, which include a plurality of two dimensional features or structures of interest in a cross-sectional image of the device. An example of a semiconductor feature of interest in a semiconductor image is one or more bounded objects, for example a plurality of bounded objects 45 arranged on a background 46. The bounded objects 45 can optionally be arranged in a pattern 47 on background 46. The bounded object can be of any suitable type, for example a circular object, a closed object, an object with a closed border, an elliptical object, an object that is approximately circular or elliptical, a rectangle, a cross section of a line pattern, a structure, a cross section of a cylinder or any combination of the foregoing. The background 46 can optionally be referred to as having a pattern, for example a pattern that receives the pattern 47 of bounded objects. The pattern of bounded objects 45, or any other pattern of features of interest or structure in an image, can optionally be referred to as a fine pattern. The background can optionally be a semiconductor substrate of any suitable type. Each of the bounded objects or structure 45 can optionally be a cross section of a line, for example a metal or conductive line for carrying electrical current, of a semiconductor device. The electrical current can include an electrical signal or power. The ring around the periphery of each bounded object can, in certain instances, be a physical material and thus structural. The ring can, in certain other instances, be an edge effect product or artifact of electron microscopy. The pattern of bounded objects can optionally be the cross section of a plurality of lines of the semiconductor device, for example a plurality of parallel lines of the device, and can optionally be called a line pattern. The pattern of bounded objects 45, or any other pattern of features of interest in an image, can optionally be referred to as a fine pattern.

Histogram 43 is a probability histogram, that is a graph that represents the probability of each outcome on the y-axis and the possible outcomes on the x-axis. The sum of the probabilities of the probability distribution are equal to 1. Grayscale probability intensity histograms can be useful for visualizing the distribution of pixel values of the image 42 because changes in the grayscale intensity pixel values can be easier to observe in a histogram than on the image itself. The scale on the x-axis of a grayscale intensity histogram can vary, for example from zero to 100, zero to 255 or zero to 65,535, depending on the type of the grayscale histogram. Zero intensity is equivalent to black. The highest intensity of the grayscale intensity is white. In cases where the image 42 has low contrast, the inherent features of the image may not be clearly visible. For example, the grayscale histogram of FIG. 2B illustrates that the grayscale intensity of image 42 is narrowly located between 50 to 80.

To enhance the visibility of a feature of interest in the image 42, which for example can be bounded objects 45 arranged in an array in image 42 on a background 46, it may be necessary to perform any suitable contrast enhancement step or method, for example as shown in step 24 of workflow 20. In the example of workflow 41, a linear rescaling contrast enhancement method is performed on image 42 to obtain a pre-processed image 48, for example as shown in FIG. 2C. Image 48 includes the features of the bounded objects 45 and background 46 of image 42. The corresponding grayscale intensity histogram 49, which has a distribution approximating a parabolic curve 50, of pre-processed image 48 is shown in FIG. 2D. A suitable linear rescaling contrast enhancement can optionally be a linear remapping of the grayscale intensity values such that they are stretched, as can be seen by comparing histogram 49 to histogram 43. The contrast enhancement step can result in the relatively darker regions appearing even darker and the relatively lighter regions appearing even lighter. For example, background 46 is darker in the pre-processed image 48 than in the original image 42, and bounded objects 45 are lighter in the pre-processed image 48 than in the original image 42 (see FIGS. 2C and 2A).

Undesirable noise may be present in image 42, or any pre-processed image therefrom. Such undesirable noise can include, for example, pixel-level noise, or grayscale intensity gradients (for example shadow effects in the background of the image), inadequate grayscale contrast, or any combination of the foregoing. Different image pre-processing operations exist to treat the different noise categories, and also within different categories, multiple methods and algorithms exist.

After performing contrast enhancements or other image pre-processing steps, for example, grayscale intensity gradients such as background shadow effects may become evident, for example as shown in image 48 shown in FIG. 2C. A shadow effect can be manifested by one portion of a feature in the image being darker than another portion of the feature in the image. Specifically with respect to image 48, for example, it can be seen from FIG. 2C that that background 46 is darker at the bottom of the image 48 than at the top of the image. This background shadow effect can optionally be removed by any suitable background correction technique, which can also be referred to as a spatial gradient correction technique. Such techniques can optionally include gradient noise reduction, as referenced above in step 24 of workflow 20. In an optional gradient noise reduction technique, a polynomial function is used to approximate the global noise in the image and that approximation is then used to make a correction to the image for that global noise. This procedure can optionally be divided into two steps: 1) a polynomial fit of the grayscale values in the two-dimensional image can be performed to determine the shadow levels in the background of the image, and then 2) the determined shadow background can be subtracted from the original image in a manner that preserves the original intensity range of the image, for example zero to 255, to perform the grayscale intensity gradient correction. A polynomial fit of 2 degrees can be used to avoid overfitting of the background; because overfitting of the image background can result in an even noisier image. Gradient noise reduction, which can optionally be called grayscale intensity gradient correction, can optionally be included to improve image segmentation results. A sample result of performing background correction of the shadow effect in image 48 of FIG. 2C is shown in image 56 of FIG. 2E and in grayscale intensity histogram 57, which has a distribution approximating a parabolic curve 58, in FIG. 2F corresponding to image 56. The entirety of the background 46 in image 56 is substantially of the same darkness, or intensity. The distribution in related histogram 57, in FIG. 2F, has changed from the distribution in histogram 49, in FIG. 2D.

After the global noise has been reduced, or otherwise, a suitable pixel-level noise reduction technique can optionally be applied to the image, for example by a Gaussian filter as shown in image 61 in FIG. 2G and in grayscale intensity histogram 62 in FIG. 2H corresponding to image 61. It can be seen in histogram 62 that an obvious separation is provided between first peak 63 and second peak 64. Peaks 63 and 64 correspond to two distinguishable features in image 61, for example a first peak 63, of lower intensity, corresponds to background 46 and second peak 64, of higher intensity, corresponds to bounded objects 45. As can be seen by comparing image 56 to image 61, image 61 contains less pixel-level noise, in other words is less pixelated, than image 56.

Image 22, for example after being pre-processed in any desired manner, such as in one or more of the pre-processing steps disclosed herein, can optionally be segmented to assign discrete values to every pixel in the image, for example to provide either a white phase or a black phase. In this regard, for example, the group of pixels of a first feature of the image can be assigned a first discrete value and the group of pixels of a second feature of the image can be assigned a second discrete value that is different than the first discrete value. For example, the pixels of bounded objects 45 can be assigned a white phase and the pixels of background 46 can be assigned a black phase, as shown in image 66 of FIG. 2I and histogram 67 of FIG. 2J. In histogram 67, first peak 68, shown at zero intensity, corresponds to background 46 and second peak 69, shown at 255 intensity, corresponds to bounded objects 45. Image 66, which can optionally be referred to as a segmented image, provides increased clarity as to which pixels belong to which feature of the image.

In an optional additional step of workflow 41, the segmented image 66 can be analyzed, as for example like in step 31 or workflow 20. In such analysis step, digital object measurements, for example an area, a radius or a center-to-center distance, can easily be obtained from the segmented image 66 due to having clarity as to which pixels belong to which class of feature. Details of such analysis step of the invention are further discussed below.

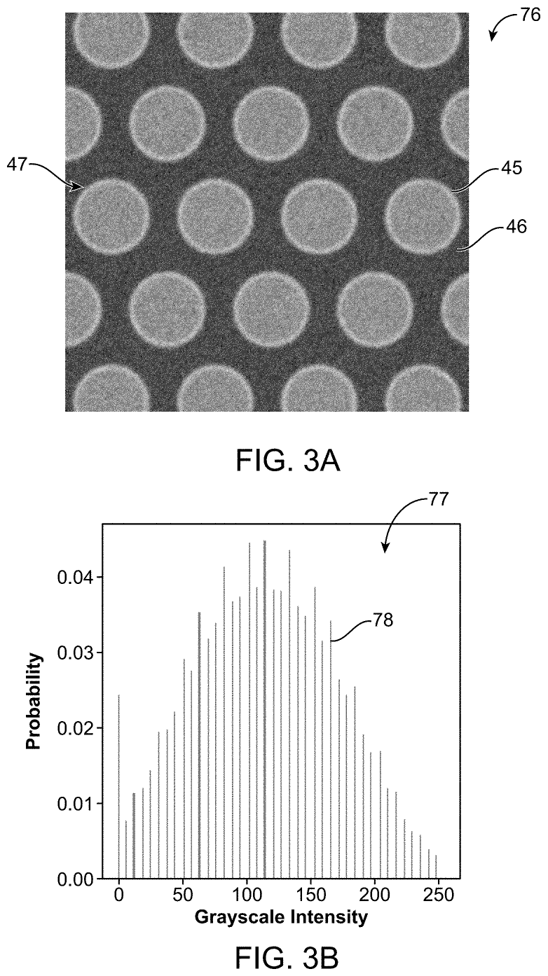

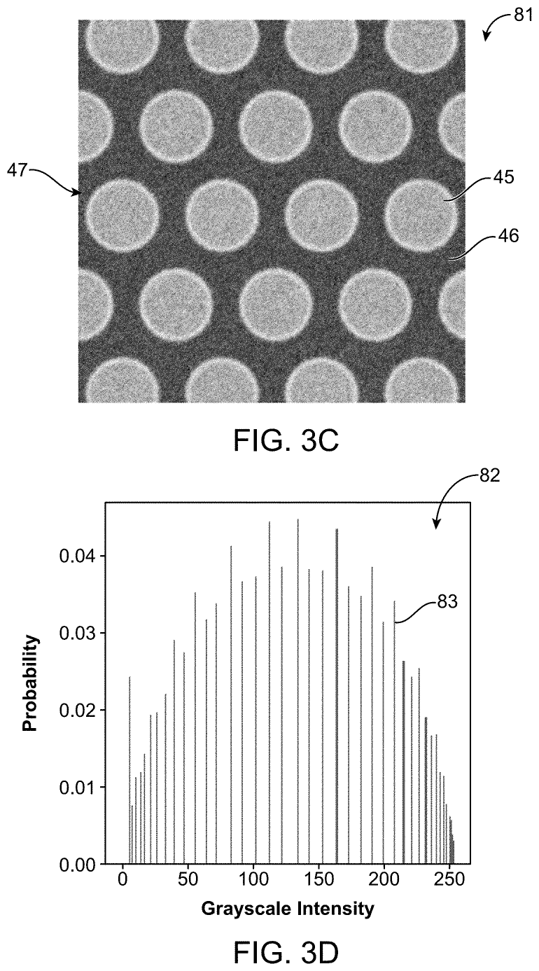

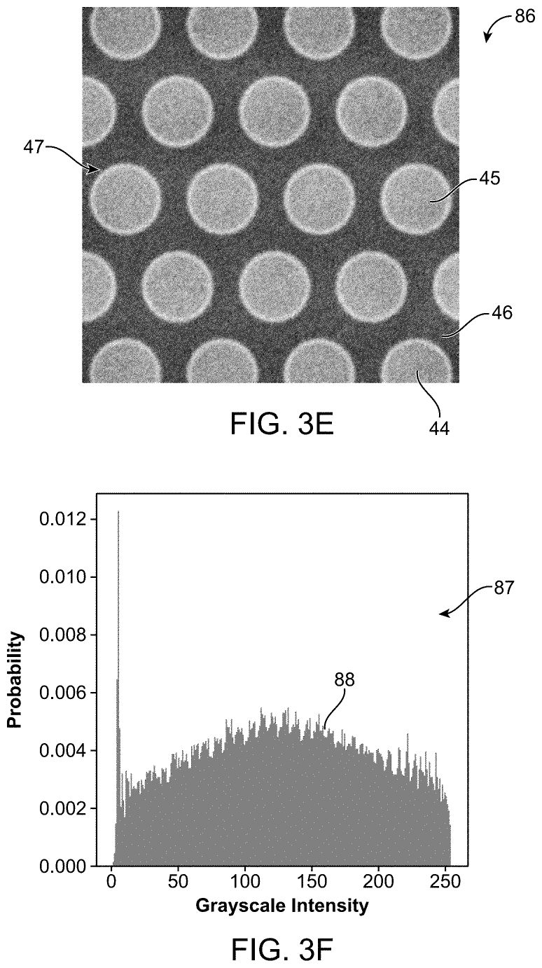

As discussed above, an acquired image, for example image 22 or image 42, may have inadequate grayscale contrast between features of interest in the image. Inadequate grayscale contrast can be addressed in the image pre-processing step of the invention, for example in step 23 in workflow 20, more specifically by any suitable contrast enhancement method, for example in step 24 of the workflow 20. For example with respect to image 42 illustrated in FIG. 2A and depicted in histogram 43 in FIG. 2B, the grayscale contrast between the features of interest, that is bounded objects 45 and background 46, may be considered inadequate. Suitable contrast enhancement methods include linear rescaling, histogram equalization and adaptive histogram equalization. Contrast enhancement is performed to increase the difference in pixel intensities in the image, which makes inherent features of interest in the image more visible. Global contrast enhancement methods, such as linear rescaling and histogram equalization, can optionally adjust all the image pixel intensities at once. Linear rescaling and histogram equalization can perform stretching and redistribution of the pixel intensities in the original image to increase the intensity difference between pixels. Local contrast enhancement methods include adaptive histogram equalization. Adaptive histogram equalization can perform histogram equalization on small neighborhoods of the image while limiting the amount of contrast enhancement in neighborhoods that experience homogeneous intensities. The results of a suitable linear rescaling technique on image 42 and corresponding distribution in histogram 43 are shown in image 76 in FIG. 3A and grayscale intensity histogram 77 in FIG. 3B. As be seen, the distribution of histogram 43, with an intensity range of 50 to 80, has been stretched in the distribution approximated by curve 78 of histogram 78 to an intensity range of zero to 255. The results of a suitable histogram equalization technique on image 42 and corresponding distribution in histogram 43 are shown in image 81 in FIG. 3C and grayscale intensity histogram 82 in FIG. 3D. As can be seen, the distribution of histogram 43, with an intensity range of 50 to 80, has been redistributed in the distribution approximated by curve 83 of histogram 82 to an intensity range of zero to 255. The results of a suitable adaptive histogram equalization technique on image 42 and corresponding distribution in histogram 43 are shown in image 86 in FIG. 3E and grayscale intensity histogram 87 in FIG. 3F. As be seen, the distribution of histogram 43, with an intensity range of 50 to 80, has been extended in the distribution approximated by curve 88 of histogram 87 to an intensity range of zero to 255. The enhancement effect of each method can be seen respectively in the corresponding images 76, 81 and 86 where the contrast between bounded objects 45 and background 46 has been increased relative to such contrast in image 42 of FIG. 2A.

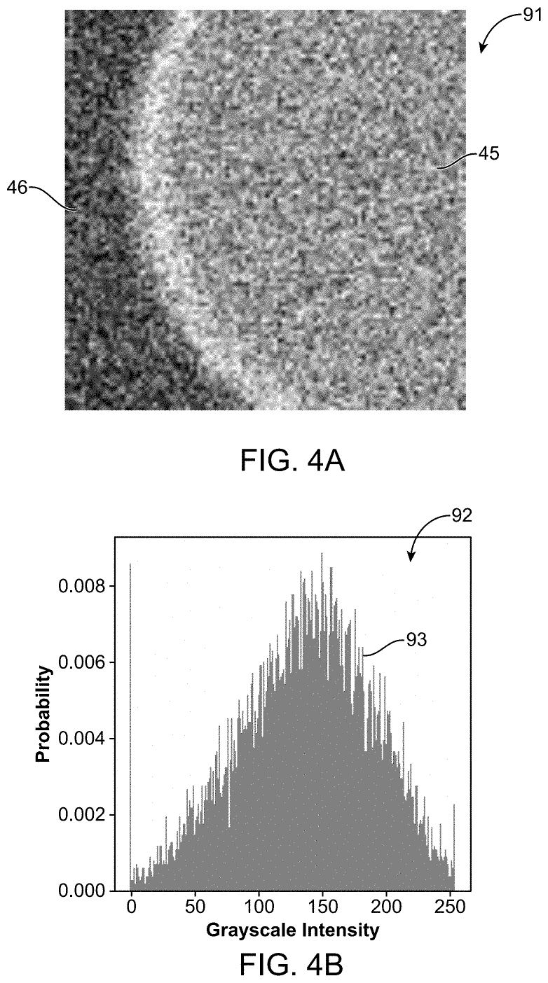

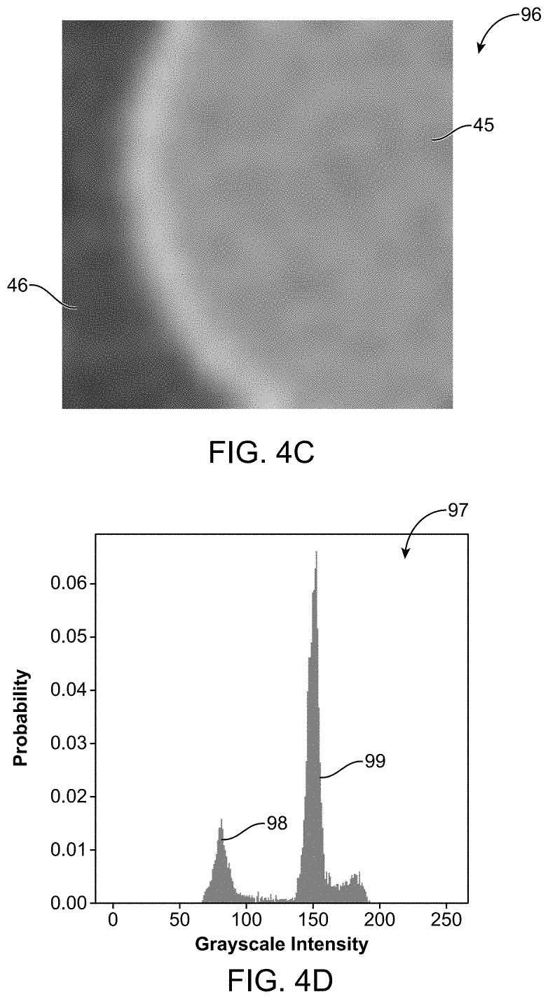

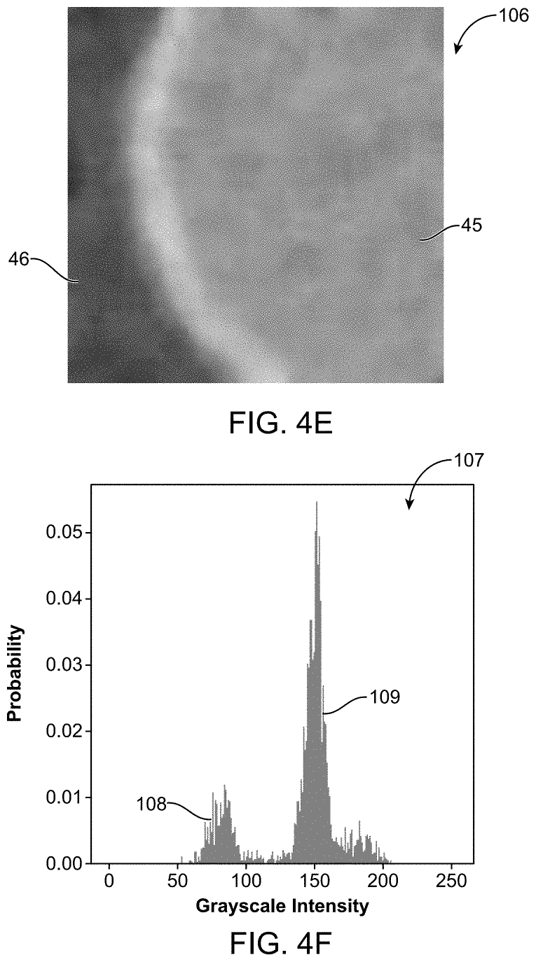

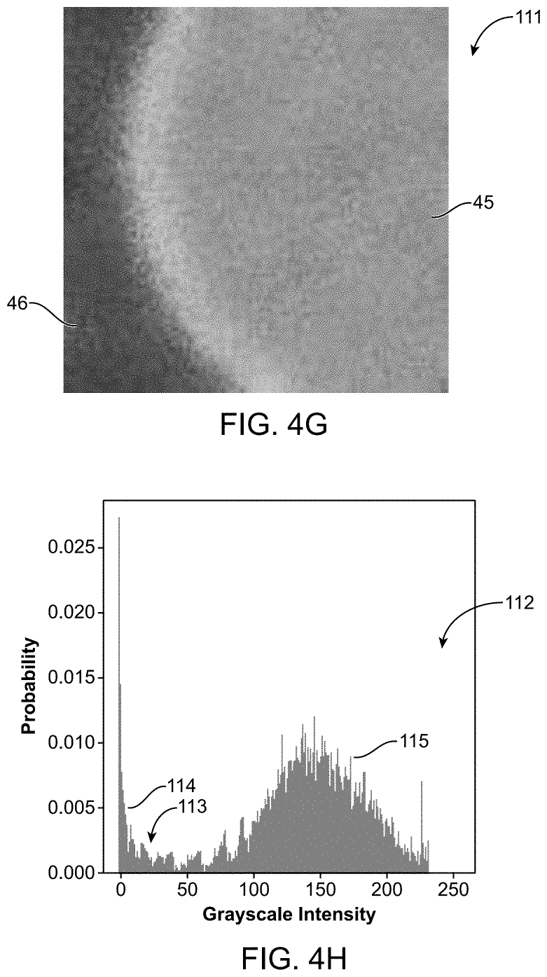

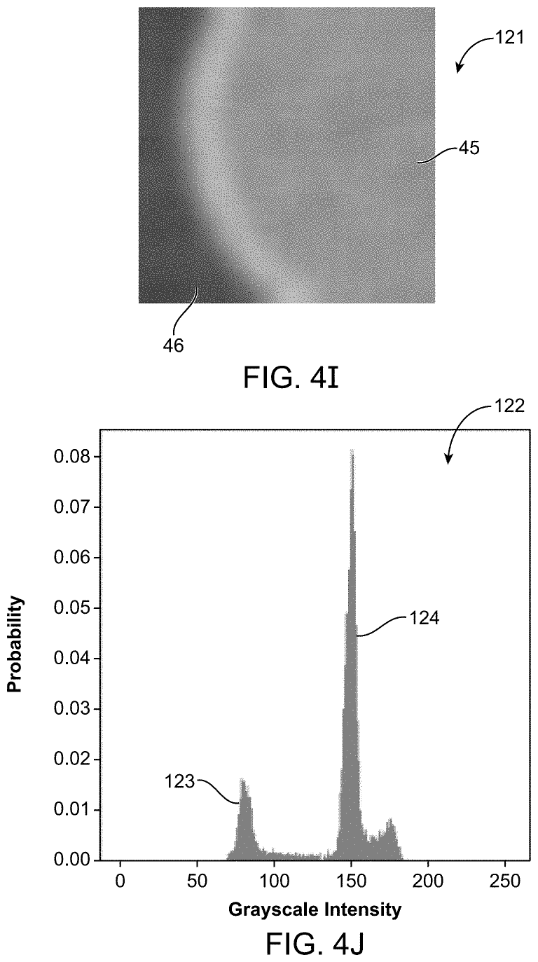

As discussed above, an acquired image, for example image 22 or image 42, may show noise in the form of severe levels of pixel-level noise, for example in a feature of interest in the image. The severity of pixel-level noise can optionally be determined by zooming in on even a smaller window (for example, a 10×10 pixel window) and observing checker-like patterns due to some randomness in the neighboring pixel grayscale values. Image 91, in FIG. 4A, is a close-up view of a portion of a bounded object 45 and adjacent background 46 taken from image 76 of FIG. 3A. Grayscale intensity histogram 92 corresponding to image 91, with a distribution approximated by a parabolic curve 93, is shown in FIG. 4B. Image noise reduction, for example pixel-level noise reduction, can be addressed in the image pre-processing step of the invention, for example in step 23 in workflow 20, more specifically by any image noise reduction technique for reducing pixel-level noise, for example in step 24 of the workflow 20. Pixel-level de-noising, which can also be referred to as filtering or blurring of the image, attempts to correct this type of noise without obscuring key features (also known as over-blurring). Filters can optionally utilize smoothing techniques in a local neighborhood to adjust the intensity of noisy pixels. The smoothing techniques can optionally involve standard filtering techniques such as Gaussian filtering, median filtering, bilateral filtering, non-local means filtering, and unsharp masking. A Gaussian filtering technique can optionally utilize a two-dimensional Gaussian kernel to smooth the center pixel in the neighborhood. A Gaussian filtering technique can be adequate for many purposes, although other techniques have special niches. A median filtering technique can optionally apply the median intensity of the neighborhood to the center pixel of the neighborhood. A bilateral filtering technique can optionally provide an edge-preserving Gaussian smoothing to the center pixel in the neighborhood. Both median filtering and bilateral filtering can preserve edges of key features in the fine patterns during the de-noising process. A non-local means filtering technique can optionally provide a patch-based filter that compares the noisy pixel to all pixels in the image. An unsharp masking technique can optionally modify one pixel at a time by applying a sequence of several local filtering techniques.

Image 96 of FIG. 4C is a sample result of a suitable Gaussian filtering technique used on noisy image 91 in FIG. 4A, and illustrates the as filtered portion of bounded object 45 and adjacent background of image 91. Grayscale intensity histogram 97 in FIG. 4D corresponds to image 96. Note that the histograms show two very distinct peaks, first peak 98 and second peak 99, which can be indicative of satisfactory image pre-processing. First peak 98 represents background 46 and second peak 99 represents the relatively lighter bounded object 45 in image 96. It may be desirable to achieve similar separation for an image that has two features of interest, although the results may vary depending on the initial image quality and the sequence of pre-processing steps used. The results of other pixel-level de-noising techniques applied to images exhibiting pixel level noise are shown in FIGS. 4E to 4L. In this regard, the results of applying median filtering to reduce the pixel level noise in image 91 of FIG. 4A is shown in image 106 in FIG. 4E and corresponding grayscale intensity histogram 107 in FIG. 4F. Two distinct peaks are shown in histogram 107, with first peak 108 representing the portion of background 46 and second peak 109 representing the relatively lighter portion of bounded object 45 in image 106. The results of applying bilateral filtering to reduce the pixel level noise in image 91 of FIG. 4A is shown in image 111 in FIG. 4G and corresponding grayscale intensity histogram 112 in FIG. 4H. An intensity region 113 near the bottom end of the intensity range, which includes first distribution or peak 114, shown in histogram 112 represents the portion of background 46 and second distribution or peak that approximates a parabolic curve 115 of higher intensity represents the portion of bounded object 45 in image 111. The results of applying non-local means filtering to reduce the pixel level noise in image 91 of FIG. 4A is shown in image 121 in FIG. 4I and corresponding grayscale intensity histogram 122 in FIG. 4J. Two distinct peaks are shown in histogram 122, with first distribution or peak 123 representing background 46 and second distribution or peak 124 representing the relatively lighter bounded object 45 in image 121. Unsharp masking is typically suited for images having low contrast edges, for example where the edge of a bounded object in the image has low contrast. A sample application of unsharp masking to the illustrated grayscale images and corresponding grayscale intensity histograms is not shown herein.

After image pre-processing steps are complete, image segmentation can be performed. Image segmentation can be addressed in the image segmentation step of the invention, for example in step 26 in workflow 20, more specifically by any global thresholding or segmentation or local thresholding or segmentation technique, for example in step 27 of the workflow 20. Segmentation is performed to define two local states, or optionally more than two local states, in the image. Segmentation involves assigning a discrete value to each pixel of a feature of interest, for example the same discrete value to each pixel of a feature of interest. The discrete value can manifest itself as black, white or another color in the segmented image. As an example of two local states, each pixel of a feature of interest in an image has a first discrete value and each pixel of the background of the image, or each pixel of another feature of interest in the image, has a second discrete value that is different than the first discrete value. The value of the segmented pixels can be arbitrary, that is be an arbitrary discrete value, although it is preferable that each pixel of a feature of interest have a discrete value that a human or computer can identify, and thus identify the feature of interest. Segmentation can optionally be performed using any suitable global segmentation method, any suitable local segmentation method, any suitable multi-segmentation method or any combination of the foregoing. Global segmentation methods assign the entire image into discrete labels at once based on the pixel intensity histogram. The global thresholding method, which is a global segmentation method, utilizes k thresholds to assign all the pixels into k+1 labels. Thresholding is performed to segment the image into at least two local states. To obtain a suitable threshold value for global thresholding, Otsu's method is a particularly suited method. The local thresholding method, which is a local segmentation method, is a method where neighborhoods of an image are segmented separately. The adaptive local thresholding method employs a global threshold method, but at smaller neighborhoods of the image. An image resulting from the image segmentation step of the invention can optionally be referred to as a segmented or segmentation image. Multi-segmentation methods can be of any suitable type, including any multi-thresholding method.

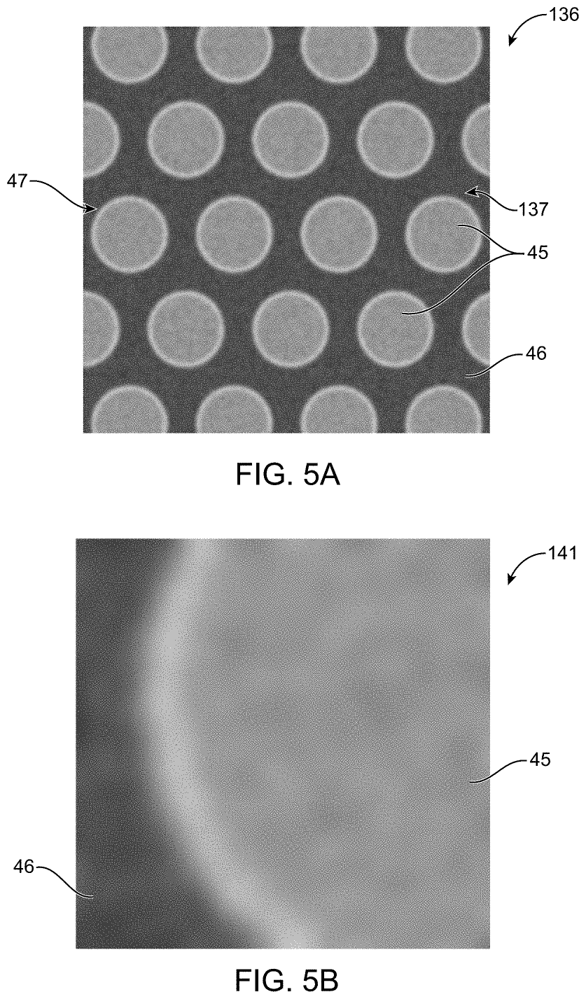

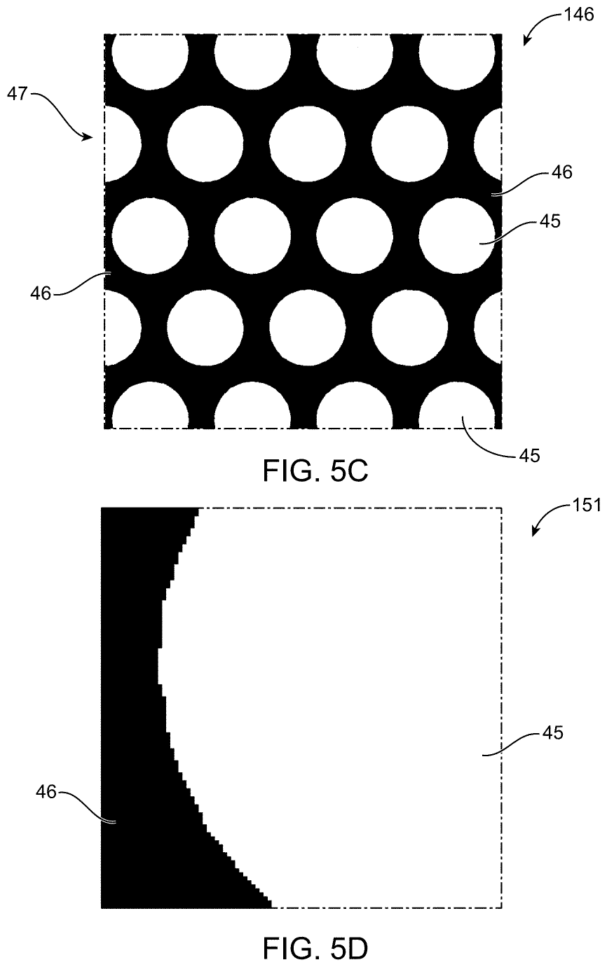

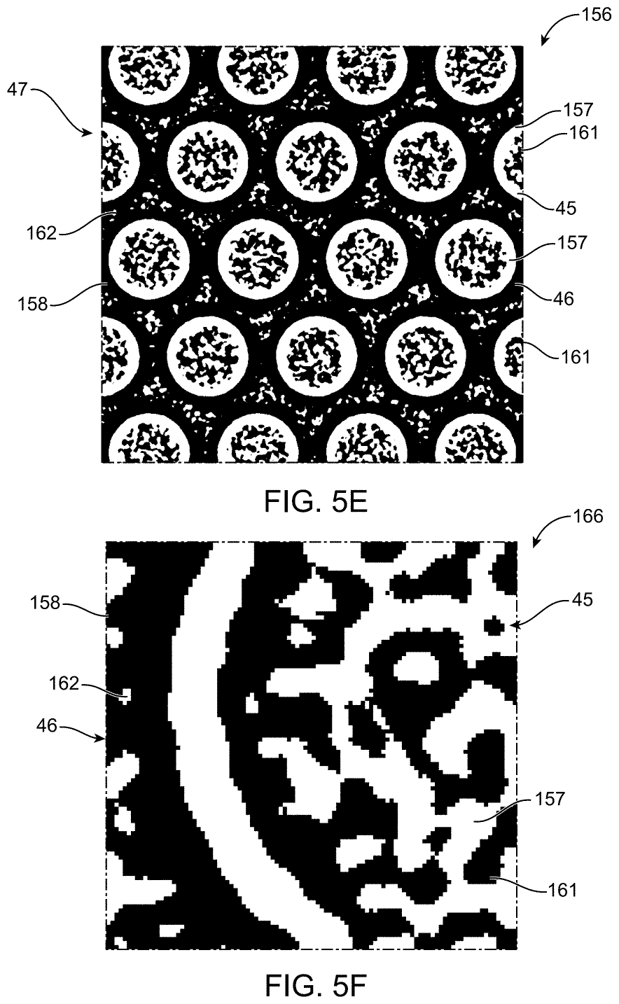

FIG. 5A is an example of a pre-processed image 136 of the invention, for example similar to image 76 in FIG. 3A. Image 136 includes a plurality of bounded objects 45 arranged in a pattern 137 in a background 46. FIG. 5B is an example of a pre-processed image 141, specifically of an enlarged view of a portion of image 136. Image 141 includes a portion of a bounded object 45 adjacent a portion of background 46. The results of applying a global thresholding technique to image 136 is shown in image 146 of FIG. 5C. Each of the pixels of each bounded object 45 in image 146 has the same discrete value, which manifests as white in image 146, while each of the pixels of background 46 in image 146 has the same discrete value, different than the discrete value of the pixels of bounded objects 45, which manifests as black in image 146. In the segmented image, the bounded objects 45, for example the entirety of the bounded objects 45, can easily be differentiated from background 46. The results of applying a global segmentation technique to image 141 is shown in image 151 of FIG. 5D. Each of the pixels of each bounded object 45 in image 151 has the same discrete value, which manifests as white in image 151, while each of the pixels of background 46 in image 151 has the same discrete value, different than the discrete value of the pixels of bounded objects 45, which manifests as black in image 151. In the segmented image 151, the portion of bounded objects 45 can easily be differentiated from background 46. The results of applying a local thresholding technique to image 136 of FIG. 5A is shown in image 156 of FIG. 5E and the results of applying a local thresholding technique to image 141 of FIG. 5B, which as discussed above is an enlarged portion of image 136, is shown in image 166 of FIG. 5F. Each of the pixels in the majority portion 157 of each bounded object 45 in images 156 and 166 has the same discrete value, which manifests as white in images 156 and 166, while each of the pixels of the majority portion 158 of background 46 in images 156 and 166 has the same discrete value, different than the discrete value of the pixels of the majority portion 157 of each bounded object 45, which manifests as black in images 156 and 166. In the segmented images 156 and 166, the bounded objects 45 can easily be differentiated from background 46. Images 146, 151, 156 and 166 can optionally be referred to as segmented or segmentation images.

After image segmentation steps are complete, image post-processing techniques can optionally be used to remove any incorrectly segmented objects due to remaining noise in the image or to remove objects by morphological description or location. Examples of post-processing techniques optionally include, but are not limited to, segmentation cleanup and morphological operations and more specifically optionally removing of holes or objects, binary erosion/dilation, or removing segmented objects that are touching any of the borders of the image. This step may be advisable if there is any leftover segmented noise in the segmented image. Image post processing can be addressed in the image post processing step of the invention, for example in step 28 in workflow 20, more specifically by any segmentation clean up or morphological operation, for example in step 29 of the workflow 20. Post-processing methods can optionally utilize morphological operations to adjust the accuracy of the segmentation or segmented image. Morphological operations can be performed on objects whose pixels are assigned to a particular label and are based on dilation, erosion, and logical operations. Dilation can include the expansion of object boundaries, whereas erosion is the contraction of boundaries. The extent of dilation and erosion can be based on a user-defined kernel. Logical operations can be used to perform specialized tasks that can be defined by the user, for example removing small objects or holes. In operations involving “small” objects for holes, the user needs to define “small.” These operations can optionally include filtering the segmented objects, that is objects in the segmented image, by object descriptions. These descriptions can optionally include object area, volume, shape, shape description, features, and object location. The objects that match these descriptions can be either removed or kept in the image. The morphological operations can optionally be applied on any local state label and in any sequence. As an example of the foregoing, the minority portions 161 of bounded objects 45 and the minority portions of background 46 in images 156 and 166 can be removed in a suitable post-processing method.

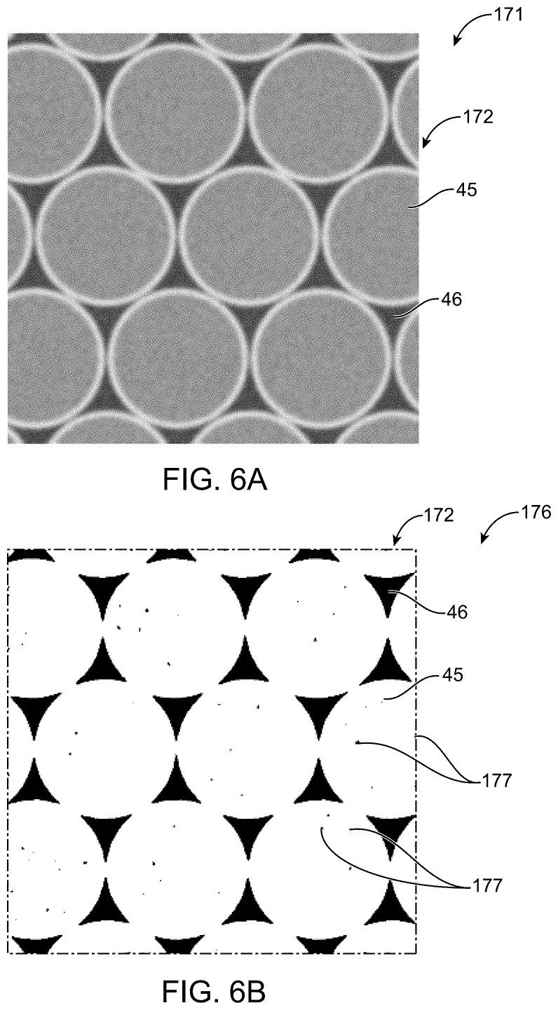

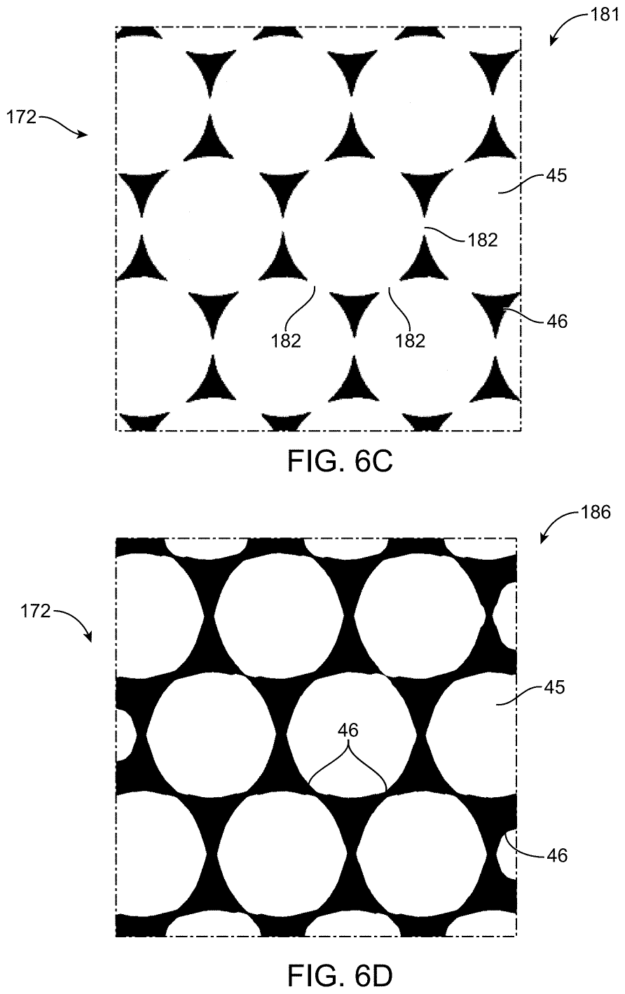

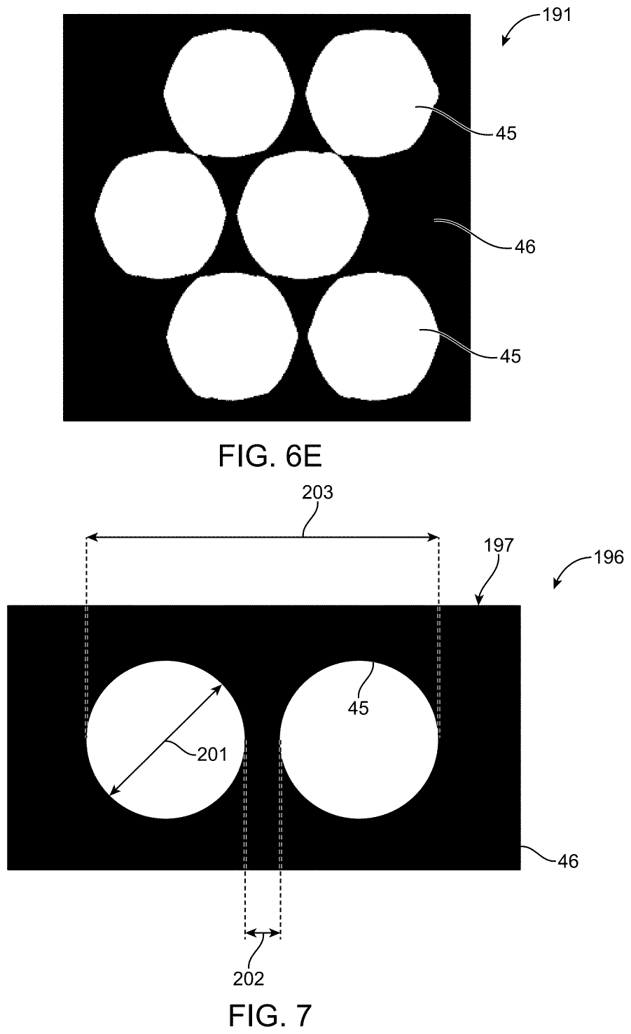

Several post-processing techniques of the invention can be illustrated with respect to image 171 shown in FIG. 6A. Image 171 can be any suitable image 22 or any corresponding image pre-processed for example from step 23 in workflow 20. Image 171 includes a plurality of features of interest, for example bounded objects or circles 45, in a suitable background 46. Bounded objects 45 can be arranged in any suitable pattern 172. Image 176 shown in FIG. 6B is any suitable corresponding segmented image created from image 171, for example from an image segmentation step of the invention, for example step 26 of workflow 20. When patterned circular objects, for example bounded objects 45, are very close to each other, the segmentation step of the invention can result in bounded objects 45 that are in contact with each other, as shown with the merged bounded objects 45 in image 176 of FIG. 6B. In this case, segmentation correction or clean up may optionally be performed. For example, small holes and objects 177 can be removed from image 176 by such segmentation correction technique, for example as shown in image 181 of FIG. 6C. Such holes and objects can be undesirable in semiconductor images because they will manifest in the conductive or metal line corresponding to a bounded object 45 and possibly reduce the consistency and thus performance of the conductive or metal line.

Any suitable binary erosion technique can optionally be performed on image 181, or other related segmented image such as image 176, to separate bounded objects 45 that have merged together in the segmented image. Such binary erosion technique can result in objects 182 connecting adjacent bounded objects 45, for example as shown in image 181 of FIG. 6C, to be removed. For example as shown in image 186 in FIG. 6D, objects 182 have been removed and adjacent bounded objects 45 are now separated from each other by a portion of background 46.

In many applications, it can be preferable that features of interest or other objects touching the image boundaries be removed. This can be valuable or desirable in an image corresponding to a semiconductor device. For example, it would not be desirable in a semiconductor device to have a conductive or metal line of the device, which can correspond to a bounded object 45 in image 22, to be exposed or accessible at a boundary of the device. For example as shown in image 191 in FIG. 6E, when compared to image 186 of FIG. 6D, bounded objects 45 in image 186 that touch the border of image 186 have been removed in image 191 of FIG. 6E. Although this completes the image post-processing step for this example, it is appreciated that other image post processing steps, for example other steps 28 or 29, can be performed with respect to the segmented image of the invention.

The steps of the invention, for example any or all of the steps discussed above, can be used for processing a CD-SEM image, a CD-TEM image or other electron microscope image into a segmented image with clearly defined features of interest and feature edges, which image can optionally be called a processed image. The method of the invention, and the resulting processed image, can facilitate further analysis of the processed image, for example for measurement and quantification of pattern or other dimensions. Such image analysis can include the measurement of critical dimensions step of the invention, for example step 31 in workflow 20, and can optionally more specifically include the spatial measurement step of the invention, for example in step 32 of the workflow 20. Depending on the type of patterns or features of interest present in the processed image, different types of measurements or analysis can be performed. Some examples of possible measurements or analysis optionally include, but are not limited to, feature sizes, areas, area fractions, distances between neighboring features, distances between neighboring features in a pattern or any combination of the foregoing. The distances between neighboring features can include the shortest distance or furthest distance.

Examples of certain of such dimensions are shown in FIG. 7 with respect to sample image 196 therein. Image 196 can be any suitable image, for example an image 22 on which any or all of steps 23, 26 and 28 of workflow 20 have been performed. Image 196 can optionally be called a processed image, and as shown is a segmented image that may or may not have required the image pre-processing step of the invention, the image post-processing step of the invention or both. The sample image 196 can include a plurality of features of interest, for example a plurality of one or more features included in integrated circuits or other semiconductor devices. Image 196 includes a plurality of two features of interest in the form of two bounded objects 45 arranged in a pattern 197, for example a pair, in background 46. Examples of sample measurements that can be extracted digitally from image 196 include a transverse dimension, a dimension or diameter 201, the shortest distance 202 between two bounded objects 45 and the furthest distance 203 between two bounded objects 45.

The measurements from image 196 can optionally be used for any further measurement or analysis step of the invention. For example, to compute the area of individual features of interest or objects, for example a bounded object 45, one can compute the total number of pixels that belong to that particular feature or object. For example, to compute the size of individual features of interest or objects, one can compute the relevant dimensions of the object depending on the shape and morphology. Such relevant dimensions can include, for example, the transverse dimension of a bounded object, such as a diameter 201 of a circle 45 in image 196, or the length and width for rectangular objects or features of interest. For example, to compute the distances between neighboring objects, one can optionally determine a pair of pixels from the different neighboring objects that are closest or furthest away based on cartesian distances, for example shortest distance 202 and furthest distance 203 with respect to bounded objects 45 in image 196. To determine which features are the closest neighbors, cartesian distances of object centroids can optionally be used. If available, the dimensions which are in pixels can be converted to physical length. The types of measurements may vary with different types of fine patterns observed in the processed image.

An interest in quantifying fine dimensions can be used to assess the consistency of such measures in bounded object, in the fine patterns or both. Such assessment can include the analysis of pattern anomalies of the invention, for example in step 32 of workflow 20 After collecting individual measurements from each pattern of features, or pairs of features where applicable, various statistical analysis can optionally be performed. Sample measurements can include, for example, measurements 201-203 with respect to the pair of bounded objects 45 in the processed image 196 in FIG. 7. Some of the primary uses for such statistical analysis may optionally include, but are not limited to, assessing the variance of the measurements or locating and identifying any anomalies in the fine pattern dimensions.

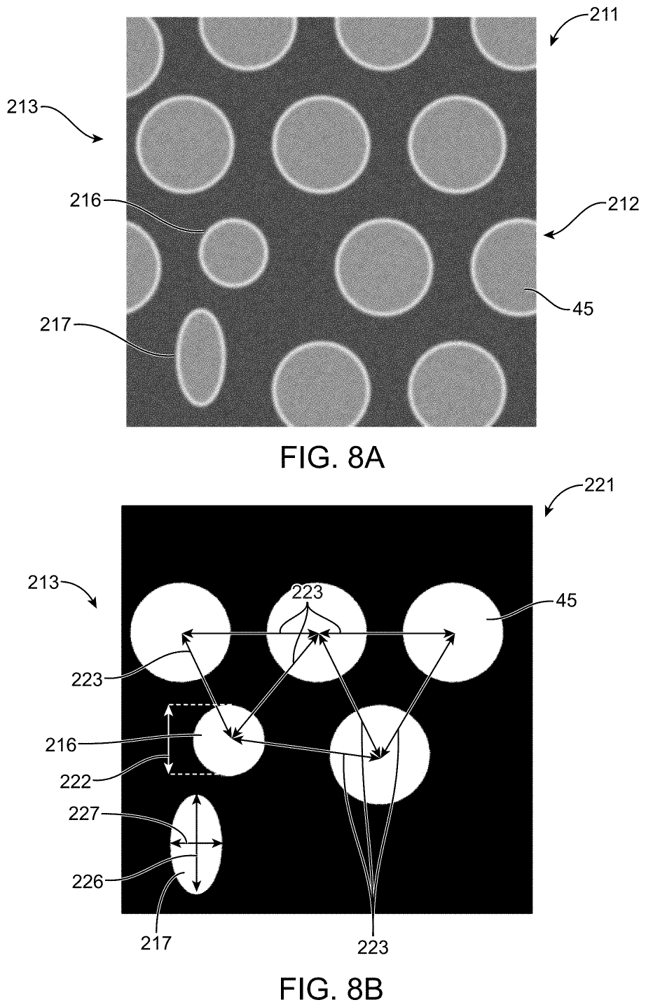

An example of identifying any anomalies in the fine pattern dimensions of an image 22 is illustrated in FIG. 8B with respect to the image 211 of FIG. 8A. Image 211 in FIG. 8A can optionally be a pre-processed image of the invention, for example in accordance with step 23 of workflow 20. Image 211 includes a plurality of features of interest or bounded objects 212, shown as a plurality of ellipses, arranged in a pattern 213 in a background 46. The features of interest include a plurality of bounded objects such as circles 45, which are desired features of interest, and one more anomalous features, which can optionally be referred to as undesired features. The anomalous features can be of any suitable type, for example an undesirably small circle or first anomalous object 216 or an oblong curved shape or ellipse or second anomalous object 217. The anomalous features in image 211 can be determined by the method of the invention, for example some or all of the steps of workflow 20. Such method can include image segmentation step 26, and optionally image post-processing step 28, to arrive at segmented image 221 shown in FIG. 8B. From the segmented image 221, any number of suitable measurements can be taken or estimated. Examples of estimated dimensions include circular diameter measurements 222, distances 223 between neighboring objects, for example the distance between the center of neighboring bounded objects or other features of interest, and major axis lengths 226 and minor axis length 227 of each bounded object or feature of interest in the segmented image 221. By taking suitable measurements, it is possible to determine which features or objects of interest in image 221 are anomalous.

The statistical values and other information obtained from the analysis of the segmented image of the invention, for example obtained in step 31 of workflow 20, can optionally be used to create models for predicting material properties of the semiconductor device, for example resistivity of a conductive line of a semiconductor device. In addition, the statistical values can optionally be used for optimizing material processing conditions, for example using machine learning algorithms, of a semiconductor device.

We claim:

1. A method for analyzing at least one bounded object in an electron microscope image, comprising segmenting the image to provide a segmented image and measuring a dimension relative to the at least one bounded object in the segmented image.

2. The method of claim 1, wherein the at least one bounded object includes a fine pattern of bounded objects in an image of a semiconductor device.

3. The method of claim 2, wherein the at least one bounded object relates to a conductive line in the semiconductor device.

4. The method of claim 1, wherein the electron microscope image is selected from the group consisting of a critical-dimension scanning electron microscope (CD-SEM) image and a critical-dimension transmission electron microscope (CD-TEM) image.

5. The method of claim 1, wherein the dimension is selected from the group consisting of a diameter, a transverse dimension, major or minor axes for an elliptical object, a length or width for a rectangular object, a distance between two bounded objects and any combination of the foregoing.

6. The method of claim 1, wherein the segmenting step is selected from the group consisting of a global segmentation method, a global thresholding method, an Otsu thresholding method, a local segmentation method, a local thresholding method, an adaptive thresholding method, a multi-segmentation method, a multi thresholding method, more than two local states and any combination of the foregoing.

7. The method of claim 1, wherein the least one bounded object includes a first pattern having a first group of pixels and a second pattern having a second group of pixels and the segmentation techniques include assigning a first discrete value to the first group of pixels and a second discrete value different than the first discrete value to the second group of pixels.

8. The method of claim 1, further comprising determining all pixels of the at least one bounded object as a function of the dimension and determining an area of the at least one bounded object by summing the number of the pixels of the at least one bounded object.

9. The method of claim 1, wherein the at least one bounded object includes neighboring first and second bounded objects and the measuring step includes quantifying distances between the neighboring first and second bounded objects, a first pixel of the first bounded object and a first pixel of the second bounded object being separated by the closest cartesian distance defining the shortest separation distance between the neighboring first and second bounded objects and a second pixel of the first bounded object and a second pixel of the second bounded object being separated by the furthest cartesian distance defining the furthest separation distance between the neighboring first and second bounded objects.

10. The method of claim 1, wherein the measuring step includes quantifying sizes relative to the at least one bounded object in the segmented image to determine dimensions of the at least one bounded object.

11. The method of claim 1, further comprising pre-processing the image before the segmenting step to provide a pre-processed image and wherein the segmenting step includes segmenting the pre-processed image.

12. The method of claim 11, wherein the pre-processing step is selected from the group consisting of a contrast enhancement method, a gradient noise reduction method, a pixel-level de-noising method and any combination of the foregoing.

13. The method of claim 12 wherein the contrast enhancement method is selected from the group consisting of a global contrast enhancement method, a linear rescaling method, a histogram equalization method, a local contrast enhancement method, an adaptive histogram equalization method and any combination of the foregoing.

14. The method of claim 12 wherein the gradient noise reduction method is selected from the group consisting of spatial intensity correction, grayscale intensity correction, background correction and any combination of the foregoing.

15. The method of claim 12, wherein the pixel-level de-noising method is selected from the group consisting of a filtering technique, a smoothing technique, a blurring technique, Gaussian filtering, bilateral filtering, median filtering, non-local means filtering, unsharp masking and any combination of the foregoing.

16. The method of claim 1, further comprising applying a post segmentation cleanup method to the segmented image before the measuring step.

17. The method of claim 16, wherein the post segmentation cleanup method is selected from the group consisting of removing holes from the segmented image, removing objects from the segmented image, morphological operations, binary erosion, binary dilation, removing segmented objects from the segmented image, removing objects touching borders of the segmented image, removing objects from the segmented image based on location, removing segmented pixel level noise and any combination of the foregoing.

18. The method of claim 1, wherein the measuring step provides quantified dimensions with respect to the at least one bounded object, further comprising detecting anomalies in the segmented image as a function of the quantified dimensions.

19. The method of claim 1, wherein the measuring step includes measuring at least one dimension with respect to the at least one bounded object to provide at least one measured dimension, further comprising using the at least one measured dimension for a step selected from the group consisting of statistical analysis, identifying anomalous features, building models for predicting materials properties, building models for optimizing materials processing and any combination of the foregoing.

20. A method for analyzing a pattern of bounded objects in an electron microscope image of a semiconductor device, comprising pre-processing the image to provide a pre-processed image, segmenting the pre-processed image to provide a segmented image and measuring a dimension in the pattern in the segmented image.

21. The method of claim 20, further comprising post-processing the segmented image before the measuring step.
